(19) United States
(12) Patent Application Publication
(10) Pub. No.: US 2008/0312400 A1
(43) Pub. Date: Dec. 18, 2008

(54) COMPOSITION FOR FORMING RESIST UNDERLAYER FILM, AND RESIST UNDERLAYER FILM

(75) Inventors: Naoki YAMASHITA, Kawasaki-shi (JP); Daisuke Kawana, Kawasaki-shi (JP); Hisanobu Harada, Kawasaki-shi (JP); Koji Yonemura, Kawasaki-shi (JP)

Correspondence Address: MORRISON & FOERSTER LLP, 425 MARKET STREET, SAN FRANCISCO, CA, 94105-2482, US

(73) Assignee: TOKYO OHKA KOGYO CO., LTD., Kawasaki-shi (JP)

(21) Appl. No.: 12/137,483

(22) Filed: Jun. 11, 2008

(30) Foreign Application Priority Data
Jun. 13, 2007 (JP) 156209/2007

(51) Int. Cl. G03F 7/004; C08G 77/28; C08G 77/04

(52) U.S. Cl. 528/30; 528/43; 528/41

(57) ABSTRACT

A composition for forming a resist underlayer film of the present invention is capable of forming a resist underlayer film which has a good matching property with a resist, by including a siloxane polymer component having a repeating unit which contains a monovalent organic group containing a sulfur atom. Thus, the composition of the resist layer film capable of forming a resist underlayer film which has a good matching property with a resist is realized.

This Nonprovisional application claims priority under 35 U.S.C. §119(a) on Patent Application No. 156209/2007 filed in Japan on Jun. 13, 2007, the entire contents of which are hereby incorporated by reference.

### FIELD OF THE INVENTION

The present invention relates to a composition for forming a resist underlayer film, which resist underlayer film functions as an antireflection film when forming a resist pattern on a substrate, and a resist underlayer film formed from the composition for forming a resist underlayer film.

### BACKGROUND OF THE INVENTION

Conventionally, in manufacturing a semiconductor device, lithography process has been used for forming a pattern on a substrate. In recent years, pattern formation is becoming more refined together with the high integration of circuit board semiconductor devices. As the pattern is further refined, the pattern formation is more effected by standing waves which is generated in an exposure step. This causes difficulty in transferring the pattern in accurate dimension. Because the standing wave is generated by interference of incident light and reflected light from the substrate, one method to solve this problem is to provide an antireflection film (resist underlayer film, hard mask) under a resist layer. The resist underlayer film is etched, by having the resist layer as a mask. The etching of the resist underlayer film is performed at the timing where the substrate has not been subjected to pattern formation.

There are organic and inorganic resist underlayer films. The organic resist underlayer film has an etching rate similar to that of the resist layer since the resist layer is also organic. Consequently, when the resist underlayer film is etched, the resist layer would also be etched. This causes difficulty in the accurate transfer of the pattern. To avoid this, the resist layer may be thickened so as to obtain the required etching resistance. However, as for the recent pattern refinement, a problem occurs that pattern collapse readily occurs in a pattern which is formed from such a thick resist layer. This is because the pattern formed from such a thick resist layer has a high aspect ratio.

Accordingly, the inorganic resist underlayer film is studied. The inorganic resist underlayer film has a largely different etching rate compared with the organic resist layer. This attains high etching selectivity. Therefore, the pattern is accurately transferable to the resist underlayer film even if the resist layer is thin. This thus solves the problem of the occurrence of the pattern collapse when the resist layer is thickened. An example of the inorganic resist underlayer film is disclosed in the following Patent Publications: Japanese Unexamined Patent Publication, Tokukai, No. 2004-310019 (published Nov. 4, 2004); and Japanese Unexamined Patent Publication, Tokukai, No. 2005-18054 (published Jan. 20, 2005). The Patent Publications of the Tokukai, No. 2004-310019 and the Tokukai, No. 2005-18074 disclose inorganic resist films formed from silicon materials.

### SUMMARY OF THE INVENTION

However, the resist underlayer films disclosed in the aforementioned Japanese Unexamined Patent Publications, Tokukai, No. 2004-310019 and Tokukai, No. 2005-18054, had not attained good matching on a boundary of the resist and the underlayer resist film. A poor matching of the resist and the resist underlayer film causes an undercut resist pattern, which would cause the pattern to collapse. The poor matching makes it difficult to transfer accurate dimensions to the substrate, because of a resist footing. Therefore, there is a demand for a composition for forming a resist underlayer film capable of forming a resist underlayer film which has a good matching property with the resist.

The present invention is made in view of the problems, and an object thereof is to provide a composition for forming a resist underlayer film, capable of forming a resist underlayer film which has a good matching property with a resist and possesses an antireflection film function. Another object of the present invention is to provide a resist underlayer film formed with the composition for forming the resist underlayer film.

In the present invention, “has a good matching property with a resist” indicates that a resist pattern to be formed on the resist underlayer film is excellent in pattern perpendicularity with respect to the resist underlayer film surface, and does not have an undercut pattern or a resist footing.

A composition according to the present invention for forming a resist underlayer film therefrom includes a siloxane polymer component which has a repeating unit as represented by General Formula (1) as follows:

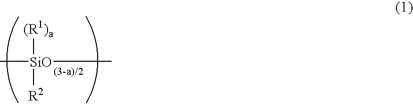

where R¹ is a hydrogen atom or a monovalent organic group, R² is a monovalent organic group containing a sulfur atom, each repeating unit may have different R¹ and/or R² from each other, and a is 0 or 1.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is an explanatory view illustrating pattern formation by using a composition according to the present invention for forming a resist underlayer film.

### DESCRIPTION OF THE EMBODIMENTS

The following description explains one embodiment of the present invention in details.

1. Composition for Forming Resist Underlayer Film

A composition according to the present invention for forming a resist underlayer film can be used in exposure to light which has a wavelength of not more than 248 nm. However, it is preferably used in exposure to an ArF laser light of 193 nm. The following description describes the composition for forming the resist underlayer film used with the ArE laser light of 193 nm.

<Repeating Unit as Represented by Formula (1)>

The composition according to the present invention for forming the resist underlayer film therefrom includes a siloxane polymer component which has a repeating unit as represented by General Formula (1) as follows:

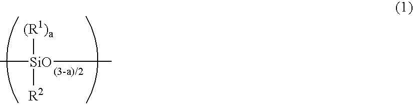

where R¹ is a hydrogen atom or a monovalent organic group, R² is a monovalent organic group containing a sulfur atom, each repeating unit may have different R¹ and/or R² from each other, and a is 0 or 1.

A resist underlayer film formed with the composition according to the present invention has a good matching property with a resist, because the composition according to the present invention includes the siloxane polymer component having the repeating unit which contains a monovalent organic group containing a sulfur atom.

The siloxane polymer component preferably contains the sulfur atom in a proportion in a range of 5 to 50 mol % with respect to a silicon atom. This proportion of the sulfur atom makes it possible to attain such a composition for forming the resist underlayer film that will provide the resist underlayer film with the good matching property with the resist, that is, makes it possible to form an excellent pattern whose perpendicularity is high. The proportion of the sulfur atom is more preferably in a range of 5 to 40 mol %, and is further preferable to be in a range of 10 to 30 mol %.

It is preferable for the monovalent organic group R² which contains the sulfur atom to be an aliphatic group or a heterocyclic group.

Examples of the aliphatic group which contains a sulfur atom encompass a mercapto group and an aliphatic group having a sulfide bonding. One example is a straight, a branched, or a cyclic C1 to C20 alkyl group, in which at least one carbon atom is replaced with a sulfur atom, or at least one hydrogen atom is replaced with —SH. —CₙH₂ₙSH (n is a natural number from 1 to 5, preferably from 1 to 3) is an example of a preferred aliphatic group which contains the sulfur atom. Examples of the heterocyclic group containing a sulfur atom encompass a thienyl group and a thiopyranyl group.

In Formula (1), a is more preferably 0. If a is 0, a ladder structure is formed, which improves curability of the resist underlayer film. Furthermore, high Si content in the siloxane polymer component is maintained. This improves inorganic property of the resist underlayer film, and thereby gives the resist underlayer film better etching selectivity with respect to an organic film.

R¹ is not particularly limited, as long as R¹ is a hydrogen atom or a monovalent organic group and the effect of the present invention is attainable.

When R¹ is a monovalent organic group, examples of R¹ encompass three-dimensionally small substituents, for example a straight or a branched C1 to C5 alkyl group, a hydroxyl group, or a C1 to C4 alkoxy group. Of the above, when R¹ contains the hydroxyl group, it is preferable that the repeating unit in which the R¹ is the hydroxyl group be in a proportion of not more than 40 mol %, with respect to all of the repeating units of Formula (1) included in the silicon polymer component. This prevents gelling of the composition for forming the resist underlayer film. For the same reason, it is preferable that the repeating unit containing the hydroxyl group be not more than 40 mol % with respect to the whole of the siloxane polymer component.

One example of a monovalent organic group is a cross-linkable monovalent organic group, for example. The cross-linkable monovalent organic group encompasses an organic group containing an epoxy group or an oxetanyl group. The curability of the resist underlayer film is increased when the monovalent organic group is such a cross-linkable monovalent organic group.

R¹ is more preferably a hydrogen atom from among the members in the Group mentioned above. This is because the hydrogen atom enables to maintain a high Si content. In addition, an Si—H bonding functions as a cross-linking site, and is considered that the bonding contributes to the increase in the curability of the resist underlayer film.

<Repeating Unit as Represented by General Formula (2)>

The composition according to the present invention for forming the resist underlayer film further preferably includes a siloxane polymer component which has a repeating unit as represented by General Formula (2) as follows:

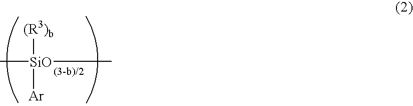

where R³ is a hydrogen atom or a monovalent organic group, Ar is a phenyl group, a naphthyl group, an anthracene group or a phenanthrene group, each repeating unit may have different R³ and/or Ar from each other, and b is 0 or 1.

The siloxane polymer component includes the repeating unit of Formula (2) containing a phenyl group, a naphthyl group, an anthracene group or a phenanthrene group. Consequently, the siloxane polymer component possesses an antireflection film function, and also can attain the good matching property with the resist.

More specifically, a resist underlayer film with a higher etching resistance against oxygen-type plasma can be prepared from the composition having the phenyl group, the naphthyl group, the anthrathene group, or the phenanthrene group. Particularly, with the composition which contains the phenyl group, good absorption for the ArF laser light of a 193 nm wavelength can be attained. With the composition which contains the naphthyl group, the anthrathene group, or the phenanthrene group, the good matching property with the resist is obtained. The composition which contains the naphthyl group is preferable of these since the naphthyl group gives the highest Si content to the siloxane polymer component among them. A high Si content enables to improve inorganic property of the resist underlayer film, and thereby gives the resist underlayer film better etching selectivity with respect to the organic film.

The repeating unit of Formula (2) is preferably in a proportion in a range of 5 to 95 mol % with respect to a whole constitutional unit of the siloxane polymer component. The repeating unit represented by Formula (2) within this range allows the composition to be formed into a resist underlayer film having the good antireflection function and capability of being patterned with high perpendicularity.

The repeating unit of Formula (2) is more preferably in a proportion in a range of 20 to 70 mol %.

In the Formula (2), b is preferably 0. If the b is 0, a ladder structure is formed, which improves curability of the resist underlayer film. Furthermore, the high Si content in the siloxane polymer component is maintained. This improves the inorganic property of the resist underlayer film, and thereby gives the resist underlayer film better etching selectivity with respect to an organic film. R³ is a hydrogen atom or a monovalent organic group, and specific examples encompass the same groups as the R¹ in General Formula (1).

<Repeating Unit as Represented by General Formula (3)>

The siloxane polymer component may further have a repeating unit as represented by General Formula (3) as follows:

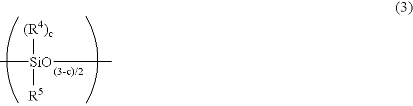

where R⁴ is a hydrogen atom, an alkyl group, a hydroxyl group, a cross-linkable monovalent organic group, or a monovalent organic group which has at least one functional group selected from the group consisting of a hydroxyl group, a polyether group, a carbonyl group, an ester group, a lactone group, an amide group, an ether group, and a nitrile group, R⁵ is a hydrogen atom or a C1 to C3 alkyl group, each repeating unit may have different R⁴ and/or R⁵ from each other, and c is 0 or 1.

A straight or a branched C1 to C5 alkyl group carbon atoms is an example of the R⁴ of the alkyl group. Compositional balance between the constitutional units is readily gained when R⁴ is the hydrogen atom, the alkyl group, or the hydroxyl group. When R⁴ is the cross-linkable monovalent organic group, curability of the resist underlayer film is improved. An example of the cross-linkable monovalent organic group is an organic group containing an epoxy group or an oxetanyl group.

The perpendicularity improves in the resist pattern, when R⁴ is the monovalent organic group which contains at least one functional group selected from the group consisting of the hydroxyl group, the polyether group, the carbonyl group, the ester group, the lactone group, the amide group, the ether group, and the nitrile group. Particularly, when R⁴ contains the hydroxyl group, it is preferable that the repeating unit in which R⁴ is the hydroxyl group be in a proportion of not more than 40 mol %, with respect to all of the repeating units of Formula (3) included in the siloxane polymer component. This further prevents the gelling of the composition for forming the resist underlayer film.

R⁴ is more preferably the hydrogen atom from among the members in the Group mentioned above. This is because the hydrogen atom enables to maintain a high Si content. An Si—H bonding functions as the cross-linking site, which allows the improvement in the curability of the underlayer resist film.

R⁵ is a hydrogen atom or a C1 to C3 alkyl group, and is more preferably a methyl group. This is because the methyl group is an organic group which can maintain a high Si content, secondly to the hydrogen atom. Although a resin having the Si—H bonding is readily soluble in an alkaline developer, a resin of an Si-Me bonding is difficult to dissolve in the alkaline developer. Therefore, for a resist film development using alkaline, the siloxane polymer component including Formula (3) allows the improvement of an alkaline developer resistance of the resist underlayer film. A good alkaline developer resistance enables to prevent damage to the resist underlayer film while developing the resist layer. In addition, a good (rectangular) pattern is attained on the substrate, following the etching.

In Formula (3), c is preferably 0. If c is 0, the ladder structure is formed, which improves the curability of the resist underlayer film. Furthermore, the high Si content of the siloxane polymer component is maintained. This improves the inorganic property of the resist underlayer film, and thereby gives the resist underlayer film better etching selectivity with respect to an organic film.

The proportion of the repeating unit of the formula (3) is preferably in a range of 5 to 40 mol % with respect to the whole constitutional unit of the siloxane polymer component, in consideration of the Si content and the alkaline developer resistance.

The siloxane polymer component may further have a repeating unit as represented by General Formula (4) as follows:

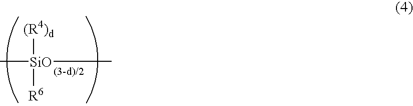

where R⁴ is as the aforementioned, R⁶ is a monovalent organic group which contains at least one functional group selected from the group consisting of an ester group and a polyether group, each repeating unit may have different R⁴ and/or R⁶ from each other, and d is 0 or 1.

Adhesiveness of the resist underlayer film according to the present invention to the resist layer is improved by having the repeating unit contain the R⁶. The R⁶ is selected from the ester group or the polyether group. The ester group is an organic group containing at least one ester group. The polyether group has a structure as in the following Formula (6):

—(CH₂)ₑ[O(CH₂)_{f}]_{g}OR′ (6)

where e is 2 to 12, f is 2 to 6; g is 2 to 200; and R′ is a hydrogen atom, an alkyl group, or another organic group.

Each of the following Formulas (7) and (8) is an example of the ester group:

—(CH₂)₂—O—C(O)Me (7)

—(CH₂)₂—C(O)—OMe (8)

Each of the following formulas (9) through (11) is an example of the polyether group:

—(CH₂)₃—(OCH₂CH₂)₇—OMe (9)

—(CH₂)₃—(OCH₂CH₂)₇—OH (10)

—(CH₂)₃—(OCH₂CH₂)₇—O—C(O)Me (11)

In Formula (4), d is preferably 0. If d is 0, the ladder structure is formed, which improves curability of the resist underlayer film. Furthermore, high Si content of the siloxane polymer component is maintained, which improves inorganic property of the resist underlayer film, and thereby gives the resist underlayer film better etching selectivity with respect to an organic film. The R⁴ is as the aforementioned.

The proportion of the repeating unit of Formula (4) is preferably in a range of 5 to 20 mol % with respect to all the siloxane polymers, in consideration of the improvement in adhesiveness.

An average molecular weight of the siloxane polymer in the siloxane polymer component is preferably in a range of 300 to 400,000. Use of the siloxane polymer in the above range allows improvement in film formation and spreadability of the composition for forming the resist underlayer film. The average molecular weight of the siloxane polymer is more preferably in a range of 500 to 100,000.

The siloxane polymer component is preferably a mixture containing a polymer A which has the repeating unit as represented by General Formula (1), and a polymer B which has the repeating unit as represented by General Formula (2).

<Polymer A>

The polymer A has the repeating unit as represented by General Formula (1). The polymer A is obtained by hydrolyzing and polycondensating monomers which can induce the repeating unit of General Formula (1). An amount of water in the hydrolyzation may be 0.2 to 10 mol per 1 mol of the monomers. An alkoxysilane or a chlorosilane, each of which is capable of inducing the repeating unit, is suitably used for each of the monomers. A metal chelate compound or a conventional well-known catalyst such as an organic acid, an inorganic acid, an organic base, or an inorganic base may be added as appropriate, during the condensation polymerization.

Examples of the metal chelate compound encompass: tetraalkoxy titanium, trialkoxy mono(acetylacetonato) titanium, tetraalkoxy zirconium, and trialkoxy mono(acetylacetonato) zirconium. Examples of the organic acid encompass: acetic acid, propionic acid, oleic acid, stearic acid, linoleic acid, salicylic acid, benzoic acid, formic acid, malonic acid, phtalic acid, fumaric acid, citric acid, and tartaric acid. Examples of the inorganic acid encompass; hydrochloric acid, sulfuric acid, nitric acid, sulfonic acid, methylsulfonic acid, tosylic acid, and trifluoromethanesulfonic acid. Examples of the organic base encompass: pyridine, pyrrole, piperazine, pyrrolidine, piperidine, picoline, trimethylamine, triethylamine, monoethanolamine, diethanolamine, dimethyl monoethanolamine, mono methyl diethanolamine, triethanolamine, diazabicyclooctane, diazabicyclononane, diazabicycloundecene, and tetramethylammonium hydroxide. Examples of the inorganic base encompass: ammonium, sodium hydroxide, potassium hydroxide, barium hydroxide, and calcium hydroxide.

If the aforementioned cross-linkable monovalent organic group is contained in the repeating unit of the siloxane polymer, a basic catalyst such as ammonium, organic amine or the like may be used. This prevents the cross-linking reaction from taking place during polymerization, and also prevents contamination with impurities such as alkaline and metal. Of the basic catalysts, it is preferable to use tetraalkylammonium hydroxide. If an epoxy group or an oxetanyl group is included as the cross-linkable monovalent organic group, an atmosphere is preferably pH 7 or more. This prevents a ring-opening of the epoxy group or the oxetanyl group. One type of the catalysts may be used, or two or more types of the catalysts may be used in combination.

For reaction, first, each of the monomers is dissolved in an organic solvent. Water is then added, in order to initiate hydrolysis reaction. The catalyst may be added in the water, or in the organic solvent.

An organic solvent hardly soluble or completely insoluble to water may be used for the organic solvent used in the reaction. Specific examples encompass: tetrahydrofuran, toluene, hexane, ethyl acetate, cyclohexanone, methyl-2-n-amylketone, propylene glycol monomethyl ether, ethylene glycol monomethyl ether, propylene glycol monoethyl ether, ethylene glycol monoethyl ether, propylene glycol dimethyl ether, diethylene glycol dimethyl ether, and a combination of these.

Next, the catalyst is neutralized, and the organic solvent layer is separated and dehydrated. The dehydration of the organic solvent layer prevents remaining silanol from undergoing a condensation reaction. Commonly known dehydration methods are taken for the dehydration, such as absorption by using a salt of magnesium sulfate or the like or synthetic zeolite, or an azeotropy dehydration method while removing the solvent.

Thereafter, the organic solvent hardly soluble or completely insoluble to water is added to the organic solvent layer. The organic solvent layer is separated and washed with water. This removes the catalyst used for the hydrolysis condensation. Here, the catalyst may be neutralized as necessary. Finally, the separated organic solvent layer is dehydrated. This obtains the polymer A.

<Polymer B>

The polymer B preferably has the repeating unit as represented by General Formula (2). The proportion of the repeating unit as represented by General Formula (2) is preferably in a range of 5 mol % to 95 mol % with respect to the whole constitutional unit of the polymer B, in consideration of the alkaline developer resistance. The polymer B may also include the repeating units as represented by General Formulas (3) and (4).

The polymer B preferably has a repeating unit as represented by General Formula (5) as follows;

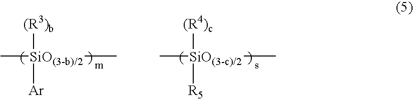

where R³, R⁴, R⁵, Ar, b and c are as the aforementioned. Each repeating unit may have different R³, R⁴, R⁵, and/or Ar from each other.

In Formula (5), b and c are preferably 0. Advantages for when b and c are 0 are as the aforementioned.

The polymer B preferably has an average molecular weight in a range of 500 to 400,000. The polymer B having the average molecular weight in the above range allows the improvement in film formation and spreadability of the composition for forming the resist underlayer film. The average molecular weight is more preferably in a range of 500 to 100,000, and is further preferably in a range of 700 to 10,000.

An included amount of the polymer B is in a range of 10 parts by weight to 200 parts by weight with respect to 100 parts by weight of the polymer A. The included amount of the siloxane polymer B in the above range allows the formation of a resist underlayer film having a good antireflection function and a good matching property with the resist film. The included amount of the polymer B is preferably in a range of 10 parts by weight to 150 parts by weight, and is further preferably in a range of 50 parts by weight to 150 parts by weight.

The composition of the resist underlayer film according to the present invention may include a solvent, a crosslinking agent, an acid generator, a quaternary ammonium compound, an organic acid, and/or the like, as necessary.

<Solvent>

The composition according to the present invention for forming the resist underlayer film may include a solvent. A type of solvent is not particularly limited, and a conventional well-known solvent may be used. Specific examples of the solvent encompass: monohydric alcohols such as methyl alcohol, ethyl alcohol, propyl alcohol, and butyl alcohol; alcohols such as ethylene glycol, diethylene glycol, propylene glycol, glycerin, trimethylolpropane, and hexanetriol; monoethers of alcohol such as ethylene glycol monomethyl ether, ethylene glycol monoethyl ether, ethylene glycol monopropyl ether, ethylene glycol monobutyl ether, diethylene glycol monomethyl ether, diethylene glycol monoethyl ether, diethylene glycol monopropyl ether, diethylene glycol monobutyl ether, propylene glycol monomethyl ether, propylene glycol monoethyl ether, propylene glycol monopropyl ether, and propylene glycol monobutyl ether; esters such as methyl acetate, ethyl acetate, butyl acetate, and ethyl lactate (EL); ketones such as acetone, methyl ethyl ketone, cycloalkyl ketone, and methyl isoamyl ketone; alcohol ethers in which the hydroxyl group of the alcohol is completely replaced with alkyl ether, such as ethylene glycol dimethyl ether, ethylene glycol diethyl ether, ethylene glycol dipropyl ether, ethylene glycol dibutyl ether, propylene glycol dimethyl ether (PGDM), propylene glycol diethyl ether, propylene glycol dibutyl ether, diethylene glycol dimethyl ether, diethylene glycol methyl ethyl ether, and diethylene glycol diethyl ether; and glycol ether esters such as propylene glycol monomethyl ether acetate (PGMEA).

The solvents may be used solely, or two or more thereof may be used in combination. An amount of the solvent used is preferably 1 to 100 fold of a weight of the siloxane polymer component. The amount of the solvent used in the above range allows improvement in spreadability of the composition for forming the resist underlayer film The amount of the solvent used is more preferably 2 to 20 fold of the weight of the siloxane polymer component.

<Crosslinking Agent>

The composition according to the present invention for forming the resist underlayer film may include a crosslinking agent. By including the crosslinking agent, the film formation is further improved. A type of the crosslinking agent is not particularly limited, and a conventional well-known crosslinking agent may be used. Specific examples of the crosslinking agent encompass: epoxy compounds such as a bisphenol-A based epoxy resin, a bisphenol-F based epoxy resin, a bisphenol-S based epoxy resin, a phenol novolac epoxy resin, a cresol novolac epoxy resin; and other compounds. Divinylbenzene, divinylsulfone, triacrylformal, glyoxat, or an acrylate, a methacrylate or the like of a polyalcohol may also be used. Furthermore, a compound having at least two reactive groups may also be used. The reactive groups of the compound have at least two amino groups of melamine, urea, benzoguanamine or glycoluril replaced with a methylol group or a lower alkoxymethyl group.

Examples of the compound in which at least two of the amino groups of melamine is replaced with the methylol group or the lower alkoxymethyl group encompass: hexamethylol melamine, hexamethoxymethylmelamine, a compound in which one to six of the hexamethylol melamine is replaced with a methoxymethyl and the combination thereof, hexamethoxyethyl melamine, hexaacyloxymethyl melamine, a compound in which one to five of the methylol group of hexamethylol melamine is acyloxymethylated and the combination thereof.

Examples of the compound in which at least two of the amino groups of urea is replaced with the methylol group or the lower alkoxymethyl group encompass: tetramethylol urea, tetramethoxymethyl urea, tetramethoxyethyl urea, and a compound in which one to four of the methylol group of the tetramethylol urea is methoxymethylated and the combination thereof.

Examples of the compound in which at least two of the amino group of benzoguanamine is replaced with the methylol group or the lower alkoxymethyl group encompass: tetramethylol guanamine, tetramethoxymethyl guanamine, and a compound in which one to four of the methylol group of the tetramethylol guanamine is acyloxymethylated and the combination thereof.

Examples of the compound in which at least two of the amino group of glycoluril is replaced with the methylol group or the lower alkoxymethyl group encompass: tetramethylol glycoluril, tetramethoxy glycoluril, tetramethoxymethyl glycoluril, a compound in which one to four methylol group of tetramethylol glycoluril is methoxymethylated and the combination thereof, and a compound in which one to four methylol group of tetramethylol glycoluril is acyloxymethylated and the combination thereof.

The crosslinking agent may be used solely or two or more thereof may be used in combination. An amount of the crosslinking agent used is preferably in a range of 0.1 parts by weight to 50 parts by weight with respect to 100 parts by weight of the siloxane polymer component. The amount of the crosslinking agent used is more preferably in a range of 0.5 parts by weight to 40 parts by weight.

<Acid Generator>

The composition according to the present invention for forming the resist underlayer film may include an acid generator. The type of the acid generator is not particularly limited, and a conventional well-known acid generator may be used. Specific examples of the acid generator which can be used include: an onium salt, a diazomethane derivative, a glyoxime derivative, a bissulfone derivative, a β-ketosulfone derivative, a disulfone derivative, a nitrobenzyl sulfonate derivative, a sulfonate derivative, and a sulfonate derivative of N-hydroxyimides.

Examples of the onium salt encompass: tetramethylammonium trifluoromethanesulfonate, tetramethylammonium nonafluorobutanesulfonate, tetra-n-butylammonium nonafluorobutanesulfonate, tetraphenylammonium nonafluorobutanesulfonate, tetramethylammonium p-toluenesulfonate, diphenyliodonium trifluoromethanesulfonate, (p-t-butoxyphenyl)phenyliodonium trifluoromethanesulfonate, diphenyliodonium p-toluenesulfonate, (p-t-butoxyphenyl)phenyliodonium p-toluenesulfonate, triphenylsulfonium trifluoromethanesulfonate, (p-t-butoxyphenyl)diphenylsulfonium trifluoromethanesulfonate, bis(p-t-butoxyphenyl)phenylsulfonium trifluoromethanesulfonate, tris(p-t-butoxyphenyl)sulfonium trifluoromethanesulfonate, triphenylsulfonium p-toluenesulfonate, (p-t-butoxyphenyl)diphenylsulfonium p-toluenesulfonate, bis(p-t-butoxyphenyl)phenylsulfonium p-toluenesulfonate, tris(p-t-butoxyphenyl)sulfonium p-toluenesulfonate, triphenylsulfonium nonafluorobutanesulfonate, triphenylsulfonium butanesulfonate, trimethylsulfonium trifluoromethanesulfonate, trimethylsulfonium p-toluenesulfonate, cyclohexylmethyl(2-oxocyclohexyl)sulfonium trifluoromethanesulfonate, cyclohexylmethyl(2-oxocyclohexyl)sulfonium p-toluenesulfonate, dimethylphenylsulfonium trifluoromethanesulfonate, dimethylphenylsulfonium p-toluenesulfonate, dicyclohexylphenylsulfonium trifluoromethanesulfonate, dicyclohexylphenylsulfonium p-toluenesulfonate, trinaphthylsulfonium trifluoromethanesulfonate, cyclohexylmethyl(2-oxocyclohexyl)sulfonium trifluoromethanesulfonate, (2-norbornyl)methyl(2-oxocyclohexyl)sulfonium trifluoromethanesulfonate, ethylenebis[methyl(2-oxocyclopentyl)sulfonium trifluoromethanesulfonate], and 1,2′-naphthylcarbonylmethyltetrahydrothiophenium triflate. An example of a preferable compound is one represented by the following General Formula (12):

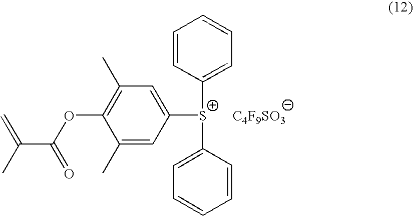

Examples of the diazomethane derivative encompass: bis(benzenesulfonyl)diazomethane, bis(p-toluenesulfonyl)diazomethane, bis(xylenesulfonyl)diazomethane, bis(cyclohexylsulfonyl)diazomethane, bis(cyclopentylsulfonyl)diazomethane, bis(n-butylsulfonyl)diazomethane, bis(isobutylsulfonyl)diazomethane, bis(sec-butylsulfonyl)diazomethane, bis(n-propylsulfonyl)diazomethane, bis(isopropylsulfonyl)diazomethane, bis(t-butylsulfonyl)diazomethane, bis(n-amylsulfonyl)diazomethane, bis(isoamylsulfonyl)diazomethane, bis(sec-amylsulfonyl)diazomethane, bis(t-amylsulfonyl)diazomethane, 1-cyclohexylsulfonyl-1-(t-butylsulfonyl)diazomethane, 1-cyclohexylsulfonyl 1-(t-amylsulfonyl)diazomethane, and 1-t-amylsulfonyl-1-(t-butylsulfonyl)diazomethane.

Examples of the glyoxime derivative encompass: bis-O-(p-toluenesulfonyl)-α-dimethylglyoxime, bis-O-(p-toluenesulfonyl)-α-diphenylglyoxime, bis-O-(p-toluenesulfonyl)-α-dicyclohexylglyoxime, bis-O-(p-toluenesulfonyl)-2,3-pentanedioneglyoxime, bis-O-(p-toluenesulfonyl)-2-methyl-3,4-pentanedioneglyoxime, bis-O-(n-butanesulfonyl)-α-dimethylglyoxime, bis-O-(n-butanesulfonyl)-α-diphenylglyoxime, bis-O-(n-butanesulfonyl)-α-dicyclohexylglyoxime, bis-O-(n-butanesulfonyl)-2,3-pentanedioneglyoxime, bis-O-(n-butanesulfonyl)-2-methyl-3,4-pentanedioneglyoxime, bis-O-{methanesulfonyl)-α-dimethylglyoxime, bis-O-(trifluoromethanesulfonyl)-α-dimethylglyoxime, bis-O-(1,1,1-trifluoroethanesulfonyl)-α-dimethylglyoxime, bis-O-(t-butanesulfonyl)-α-dimethylglyoxime, bis-O-(perfluorooctanesulfonyl)-α-dimethylglyoxime, bis-O-(cyclohexanesulfonyl)-α-dimethylglyoxime, bis-O-(benzenesulfonyl)-α-dimethylglyoxime, bis-O-(p-fluorobenzenesulfonyl)-α-dimethylglyoxime, bis-O-(p-t-butylbenzenesulfonyl)-α-dimethylglyoxime, bis-O-(xylenesulfonyl)-α-dimethylglyoxime, and bis-O-(camphorsulfonyl)-α-dimethylglyoxime.

Examples of the bis-sulfone derivative encompass: bis-naphthylsulfonylmethane, bis-trifluoromethylsulfonylmethane, bis-methylsulfonylmethane, bis-ethylsulfonylmethane, bis-propylsulfonylmethane, bis-isopropylsulfonylmethane, bis-p-toluenesulfonylmethane, and bis-benzenesulfonylmethane.

Examples of the β-ketosulfone derivative encompass: 2-cyclohexylcarbonyl-2-(p-toluenesulfonyl)propane, 2-isopropylcarbonyl-2-(p-toluenesulfonyl)propane, and the like.

Examples of the disulfone derivative encompass disulfone derivatives of diphenyldisulfone derivatives, dicyclohexyldisulfone derivatives and the like.

Examples of the nitrobenzyl sulfonate derivatives encompass 2,6-dinitrobenzyl p-toluenesulfonate, 2,4-dinitrobenzyl p-toluenesulfonate, and the like.

Examples of the sulfonate derivative encompass: 1,2,3-tris(methanesulfonyloxy)benzene, 1,2,3-tris(trifluoromethanesulfonyloxy)benzene, and 1,2,3-tris(p-toluenesulfonyloxy)benzene.

Examples of the sulfonate derivative of N-hydroxyimides encompass: N-hydroxysuccinimide methanesulfonate, N-hydroxysuccinimide trifluoromethanesulfonate, N-hydroxysuccinimide ethanesulfonate, N-hydroxysuccinimide 1-propanesulfonate, N-hydroxysuccinimide 2-propanesulfonate, N-hydroxysuccinimide 1-pentanesulfonate, N-hydroxysuccinimide 1-octanesulfonate, N-hydroxysuccinimide p-toluenesulfonate, N-hydroxysuccinimide p-methoxybenzenesulfonate, N-hydroxysuccinimide 2-chloroethanesulfonate, N-hydroxysuccinimide benzenesulfonate, N-hydroxysuccinimide 2,4,6-trimethylbenzenesulfonate, N-hydroxysuccinimide 1-naphthalenesulfonate, N-hydroxysuccinimide 2-naphthalenesulfonate, N-hydroxy-2-phenylsuccinimide methanesulfonate, N-hydroxymaleimide methanesulfonate, N-hydroxymaleimide ethanesulfonate, N-hydroxy-2-phenylmaleimide methanesulfonate, N-hydroxyglutarimide methanesulfonate, N-hydroxyglutarimide benzenesulfonate, N-hydroxyphthalimide methanesulfonate, N-hydroxyphthalimide benzenesulfonate, N-hydroxyphthalimide trifluoromethanesulfonate, N-hydroxyphthalimide p-toluenesulfonate, N-hydroxynaphthalimide methanesulfonate, N-hydroxynaphthalimide benzenesulfonate, N-hydroxy-5-norbornene-2,3-dicarboxyimide methanesulfonate, N-hydroxy-5-norbornene-2,3-dicarboxyimide trifluoromethanesulfonate, and N-hydroxy-5-norbornene-2,3-dicarboxyimide p-toluenesulfonate.

The acid generator may be used solely, or two or more thereof may be used in combination. An amount of the acid generator used is preferably in a range of 0.1 parts by weight to 50 parts by weight with respect to 100 parts by weight of the siloxane polymer component. The acid generator used in the above range allows the formation of a resist pattern with good perpendicularity. The amount of the acid generator used is more preferably in a range of 0.5 parts by weight to 40 parts by weight.

<Quaternary Ammonium Compound>

The composition according to the present invention for forming the resist underlayer film may further include a quaternary ammonium compound. The quaternary ammonium compound in the composition prevents film wearing of the resist layer formed on the resist underlayer film. Thus, it is possible to form a good resist pattern. More specifically, an example of the quaternary ammonium compound is a quaternary ammonium compound as represented by General Formula (13) as follows:

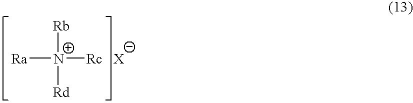

where Ra through Rd each independently or identically are a hydrocarbon radical(s), and X⁻ denotes a counter anion.

Examples of the hydrocarbon radicals of Ra through Rd encompass straight, branched or cyclic, and saturated or unsaturated hydrocarbon radicals. The hydrocarbon radicals may have a substituent. Examples of the straight and branched hydrocarbon radicals encompass: a methyl group, a methylene group, an ethyl group, an ethylene group, a propyl group, a propylene group, an isopropyl group, an n-butyl group, an isobutyl group, an isopropylene group, a secondary butyl group, a tertiary butyl group, an amyl group, an isoamyl group, a tertiary amyl group, a hexyl group, a heptyl group, an octyl group, an iso-octyl group, a 2-ethylhexyl group, a tertiary octyl group, a nonyl group, an isononyl group, a decyl group, and an isodecyl group.

Examples of the cyclic hydrocarbon radicals encompass a cycloalkyl group and an aryl group. The cycloalkyl group encompasses groups in which at least one hydrogen atom is removed from a polycycloalkane such as cycloalkane, bicycloalkane, tricycloalkane, and tetracycloalkane. More specifically, examples encompass groups in which one hydrogen atom is removed from the polycycloalkane such as a monocycloalkane for example cyclopentane and cyclohexane, adamantane, norbornane, isobornane, tricyclodecane, and tetracyclododecane. Examples of the aryl group encompass: a phenyl group, a naphthyl group, a methylphenyl group, an ethylphenyl group, a tolyl group, a chlorophenyl group, a bromophenyl group, and a fluorophenyl group.

Examples of the substituent encompass an OH group and a C1 to C3 alkoxy group, for example.

A total number of carbon atoms for Ra through Rd is preferably at least 10. By having the total carbon number to be at least 10, it is possible to reduce the resist footing of the resist pattern formed on the resist underlayer film, as well as improving the shape of the pattern. It is more preferable for at least one of the Ra through Rd to have at least 8 carbon atoms. This thus allows further reduction of the resist footing of the resist pattern formed on the resist underlayer film. The total number of carbon atoms included in the Ra through Rd is further preferably not more than 25. This further allows the reduction of the resist footing.

Examples of the counter anion X encompass: OH⁻, Cl⁻, Br⁻, F⁻, alkylcarboxylate anion, and aralkylcarboxylate anion.

An amount of the quaternary ammonium compound added is preferably in a range of 0.01 parts by weight to 10 parts by weight with respect to 100 parts by weight of the siloxane polymer component. This amount prevents the film wearing of the resist layer to be formed on the resist underlayer film, and allows improvement in the shape of the resist pattern to be formed. The amount of the quaternary ammonium compound is further preferably in a range of 0.1 parts by weight to 5 parts by weight, and is most preferred to be in a range of 0.1 parts by weight to 3 parts by weight.

<Organic Acid>

The composition according to the present invention for forming the resist underlayer film may further include an organic acid. The addition of the organic acid prevents deterioration of the composition over time, which is caused by the addition of the quaternary ammonium compound.

Examples of the organic acid encompass an organic carboxylic acid, an organic phosphonic acid, and an organic sulfonic acid. Examples of the organic carboxylic acid encompass: aliphatic monocarboxylic acids such as formic acid, acetic acid, propionic acid, butyric acid, lauric acid, palmitic acid, and stearic acid; unsaturated aliphatic monocarboxylic acids such as oleic acid and linoleic acid; aliphatic dicarboxylic acids such as oxalic acid, malonic acid, succinic acid, adipic acid, and maleic acid; oxycarboxylic acids such as lactic acid, gluconic acid, malic acid, tartaric acid, and citric acid; and aromatic carboxylic acids such as benzoic acid, mandelic acid, salicylic acid, and phthalic acid. Malonic acid is more preferred of the aforementioned organic acids.

An amount of the organic acid added is preferably in a range of 0.01 parts by weight to 10 parts by weight with respect to 100 parts by weight of the siloxane polymer component. Long-term stability of the composition of the resist underlayer film is further improved by adding at least 0.01 parts by weight of the organic acid. The amount of the organic acid is not more than 10 parts by weight in order to suppress the organic acid inhibiting the film wearing prevention effect by the quaternary ammonium compound.

The weight ratio of the organic acid to the quaternary ammonium compound is preferably in a range of 100:20 to 100:60, and is more preferably in a range of 100:30 to 100:50. The weight ratio in the above range reduces the resist footing of the resist pattern formed on the resist underlayer film. The pattern shape is thus improved, and the long-term stability of the composition for forming the resist underlayer film is further improved.

The composition according to the present invention for forming the resist underlayer film is obtained by combining, to the siloxane polymer component, the aforementioned solvent, crosslinking agent, acid generator, quaternary ammonium compound, organic acid and/or the like as necessary. The obtained composition of the resist underlayer film is filtered by a filter or the like if necessary.

2. Resist Underlayer Film

A resist underlayer film according to the present invention is formed with the composition for forming the resist underlayer film. More specifically, the composition for forming the resist underlayer film is applied on a process-target object such as a substrate or the like (preferably on an organic bottom layer formed on the substrate) by using a spin coater, a slit nozzle coater, or the like. The applied composition is then thermally dried. This thus obtains the resist underlayer film. Heating of the composition is carried out by a one-step heating method or a multi-step heating method. The multi-step heating method may, for example, heat the composition for 60 to 120 seconds at a temperature in a range of 100° C. to 120° C., then heat the composition for 60 to 120 seconds at a temperature in a range of 200° C. to 250° C. A thickness of the resist underlayer film of the present invention formed in this way is preferably in a range of 15 nm to 200 nm.

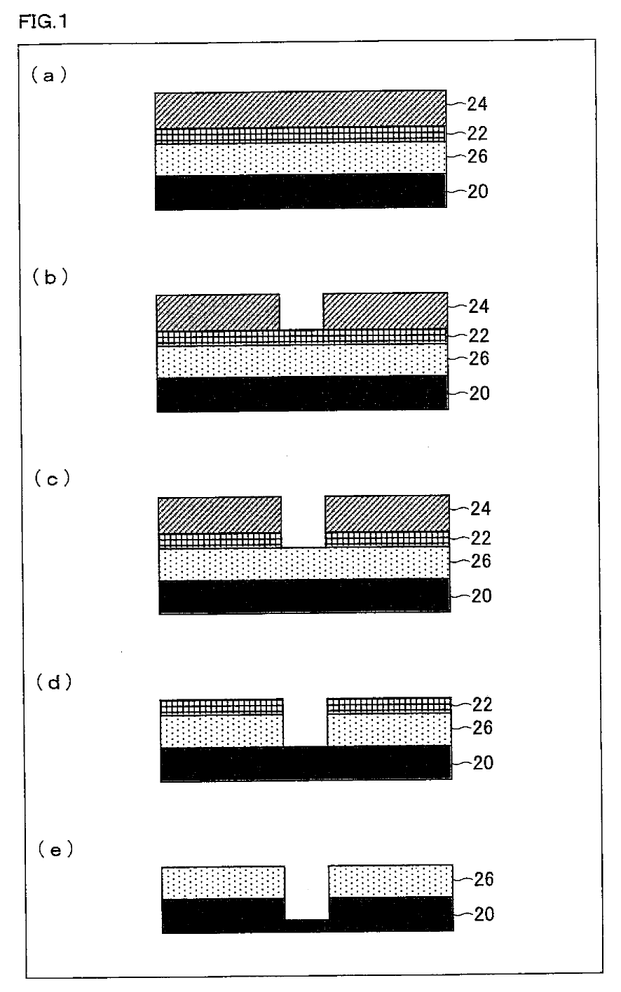

The resist underlayer film according to the present invention may be used as an intermediate layer in a multilayered resist process such as a three-layered resist process. The following description explains one example of a pattern formation method by using the resist underlayer film according to the present invention, with reference to drawings. FIG. 1 is a cross sectional view illustrating a formation step of a pattern according to the present embodiment.

As illustrated in (a) of FIG. 1, a conventional well-known composition for forming an organic bottom layer is applied on a substrate 20 by spin coating or the like, and is baked at a predetermined temperature. This forms an organic bottom layer 26. Next, the composition according to the present invention for forming the resist underlayer film is applied on the organic bottom layer 26 by spin coating or the like, and is baked at a predetermined temperature. This forms a resist underlayer film 22. Thereafter, the conventional well-known resist composition is applied as similar to the aforementioned by spin coating or the like, and is prebaked at a predetermined temperature (preferably in a range of 50° C. to 300° C., for 30 to 300 seconds). This forms a resist film 24 (preferably having a film thickness in a range of 100 nm to 300 nm).

Following this, as illustrated in (b) of FIG. 1, a predetermined pattern is formed on the resist film 24 by exposure and development. The resist underlayer film is etched by having the patterned resist film 24 as a mask. (c) of FIG. 1 illustrates the resist pattern transferred to the resist underlayer film 22. An etching gas used herein for example is a CF type (i.e. CF₄), a Cl type (i.e. CCl₄), an SF type (i.e. SF₆), or the like. Thereafter, the organic bottom layer 26 is etched by having the resist layer 24 and the resist underlayer film 22 as the mask. This thus transfers the resist pattern to the organic bottom layer 26, as illustrated in (d) of FIG. 1. The etching gas here for example is an O₂ type (i.e. O₂/N₂). The resist film 24 may be removed by etching while the etching of the organic bottom layer 26 is performed. Finally, as illustrated in (e) of FIG. 1, the pattern is transferred to the substrate 20, by having the resist underlayer film 22 and the organic bottom layer 26 as the mask. The etching gas used herein may be a CF type (i.e. CF₄), a CHP type (i.e. CH₃), a Cl type (i.e. CCl₄), an SF type (SF₆), or other types. The resist underlayer film 22 may be removed by etching while the etching of the substrate 20 is performed.

The organic bottom layer 26 operates as a mask for the etching of the substrate 20. Consequently, it is desirable for the organic bottom layer 26 to have a high etching resistance. The organic bottom layer 26 that has been subjected to spin coating on the substrate 20 is preferably cross-linked with heat or an acid. This is because the organic bottom layer 26 requires to be uncombined with the resist underlayer film 22, which is the upper layer of the organic bottom layer 26. More specifically, the following resins may be used: cresol novolac, naphthol novolac, catordicyclopentadiene novolac, amorphous carbon, polyhydroxystyrene, (meth)acrylate, polyimide, polysulfone, or the like.

A conventional well-known composition may be used for the resist composition in forming the resist film 24, such as a combination of a base resin, an organic solvent, and an acid generator, for example. Examples of the base resin encompass: polyhydroxystyrene and a derivative thereof, polyacrylic acid and a derivative thereof, polymethacrylic acid and a derivative thereof, a copolymer selected from hydroxystyrene, acrylic acid and methacrylic acid and a derivatives thereof, a copolymer of at least three types selected from cycloolefin and a derivative thereof and acrylic acid and a derivative thereof, polynorbornene, and a high molecule polymer of at least one type selected from the group consisting of a metathesis ring-opening polymer. The “derivative” here denotes one which has been subjected to derivation and a main framework remains, as like where an acrylate and the like is contained in the acrylic acid derivative, a methacrylate and the like is contained in the methacrylic acid derivative, and an alkoxystyrene and the like is contained in the hydroxystyrene derivative.

An example of the resist composition for the KrF excimer laser is a copolymer of one type of a polyhydroxystyrene, a hydroxystyrene, or a styrene, and one type of an acrylate, a methacrylate, or a maleimide-N-carboxylate. Examples of the resist composition for the ArF excimer laser encompass: acrylates, methacrylates, copolymers of norbornene and maleic anhydride, copolymers of tetracyclododecene and maleic anhydride, polynorbornene, and metathesis polymers of ring-opening polymerization. However, the resist compositions are not limited to these polymers.

### EXAMPLES

The following description provides examples of the present invention. The present invention is not limited to the examples.

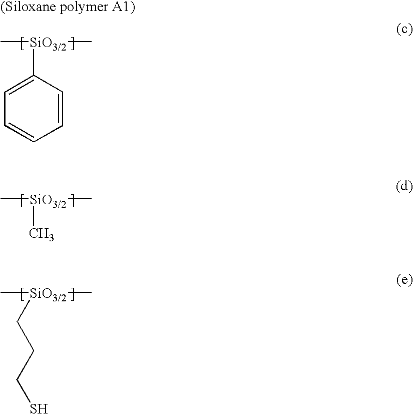

where (c):(d):(e)=10:70:20 (molar ratio to add)

The siloxane polymer A1 was synthesized by the following procedures. To begin with, 47.8 g of water and 4.4 g of 35% hydrochloric acid were added in a 1 L four-neck flask. The four-neck flask was provided with a stirrer, a reflux condenser, a dropping funnel, and a thermometer. Then, 252.2 g of toluene solution containing 16.3 g (0.083 mol) of 3-mercaptopropyltrimethoxysilane, 5.7 g (0.042 mol) of phenyltrimethoxysilane, and 39.7 g (0.291 mol) of methyltrimethoxysilane was dropped into the flask at a reacting temperature in a range of 10 to 20° C. over two hours. After the dropping was finished, the reacting solution was cured for two hours at the same temperature. Following the curing, the reacting solution was analyzed with gas chromatography (GC) to check that all the materials were completely consumed. Next, the solution was left standing, and then separated so as to collect an oil layer. The oil layer was washed with a 5% sodium hydrogen carbonate aqueous solution, and then washed with water. Finally, a toluene oil layer was collected.

A solvent was evaporated off from the obtained oil layer by an evaporator. As a result, 33.8 g of 3-mercaptopropylsilsesquioxane.phenylsilsesquioxane. methylsilsesquioxane copolymer (molar composition ratio of 20:10:70) was obtained. This copolymer was a white powder. The obtained copolymer was analyzed with gel permeation chromatography (GPC). The GPC analysis showed that an average molecular weight (Mw in terms of polystyrene) was 1,230, and a degree of dispersion (Mw/Mn in terms of polystyrene) was 1.4. The following shows a spectral data of the obtained copolymer: Infrared absorption spectrum (IR) data; 2840 cm⁻¹ (—SH), 1030-1120 cm⁻¹ (Si—O) (IR Prestige-21, manufactured by SHIMADZU Corporation); and Nuclear magnetic resonance spectrum (NMR) data: 0.565-1.021 ppm (bs), 1.183-2.505 ppm (bs), 7.550-8.615 ppm (bs) (1H-NMR solvent: DMSO-d6, 400 MHz NMR measuring device, manufactured by JEOL Ltd.)

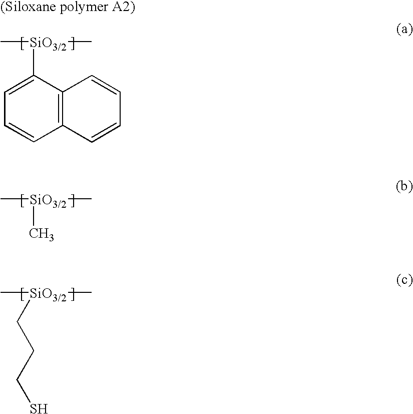

where (a):(b):(c)=50:30:20 (molar ratio to add)

A siloxane polymer A2 was synthesized in the same way as the synthesis of the siloxane polymer A1, except that phenyltrimethoxysilane was used in place of 1-naphthyltrimethoxysilane, and a proportion of the monomer was changed.

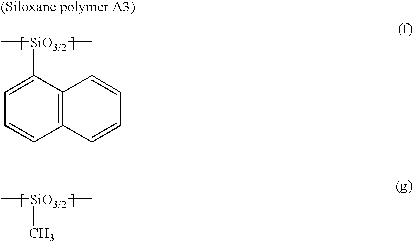

where (f):(g)=50:50 (molar ratio to add) The siloxane polymer A3 was synthesized by the following procedures. To begin with, 97.1 g (5.39 mol) of water and 9.1 g of 35% hydrochloric acid aqueous solution were added in a 1 L four-neck flask. Then, 252.2 g of a toluene solution containing 108.5 g (0.437 mol) of 1-naphthyltrimethoxysilane and 59.5 g (0.437 mol) of methyltrimethoxysilane was dropped into the four-neck flask at a reacting temperature in a range of 10 to 20° C. After the dropping was finished, the solution was cured for two hours at the same temperature. Following the curing, the reacting solution was analyzed with gas chromatography (GC) to check that all the materials were completely consumed. Next, the solution was left standing, and then separated so as to collect an oil layer. The oil layer was washed with a 5% sodium hydrogen carbonate aqueous solution, and then washed with water. Finally, a toluene oil layer was collected. A solvent was evaporated off from obtained the oil layer by an evaporator. As a result, 117.2 g of 1-naphthylsilsesquioxane. methylsilsesquioxane copolymer was obtained. The copolymer thus obtained was analyzed with gel permeation chromatography GPC). The GPC analysis showed that the Mw was 1,000, and the degree of dispersion (Mw/Mn in terms of polystyrene) was 1.2. The following shows a spectrum data of the obtained siloxane polymer A3: Infrared absorption spectrum (IR) data: 3055, 1504 cm⁻¹ (naphthalene), 1026-1111 cm⁻¹ (Si—O) (IR Prestige-21, manufactured by SHIMADZU Corporation); and Nuclear magnetic resonance spectrum (NMR) data: 0.182 ppm (bs), 7.021-8.252 ppm (b) (1H-NMR solvent: CDCl3, 400MHz NMR measuring device, manufactured by JEOL Ltd.)

(Siloxane Polymer B)

In the present example, a siloxane polymer as represented by General Formula (15) as follows was used as the siloxane polymer B:

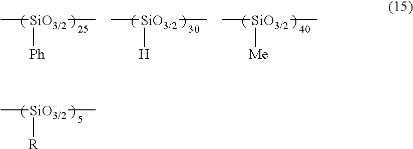

where R is —(CH₂)₂—OC(O)Me, Me is a methyl group, and numbers shown outside the brackets are in units of mol %.

More specifically, the siloxane polymer B was synthesized by the following procedures. To begin with, 13.2 g (0.0625 mol) of phenyltrichlorosilane, 10.2 g (0.075 mol) of trichlorosilane, 14.9 g (0.1 mol) of methyltrichlorosilane, and 2.8 g (0.0125 mol) of acetoxyethyltrichlorosilane were added and mixed with 120 g of PGMEA, and was reacted in the presence of nitrogen. After the reaction, a solution which mixes 200 g of PGMEA and 10 g (0.555 mol) of water was added to the solution thus mixed over an hour. This solution was further stirred for one hour, at a temperature of 20° C. A resin solution was concentrated to approximately 10 wt % by a rotary evaporator set to a temperature of 40° C. Approximately 40 g of ethanol was added to the resin solution. Again, the solution was vaporized to approximately 20 wt %. The solution was then placed in a different reacting container, and PGMEA was added so as to dilute the solution to 10 wt %. This solution was filtered with a 0.2 micron PTFE filter. The siloxane polymer B was thus obtained by the above steps. The molecular amount of the siloxane polymer B due to the GPC analysis had, in terms of polystyrene, the average molecular weight (Mw) of 9,700.

[Preparation of Composition for Forming Resist Underlayer Film]

### Example 1

Fifty parts by weight of the siloxane polymer A1, fifty parts by weight of the siloxane polymer B, 0.3 parts by weight of hexadecyltrimethylammoniumacetate, and 0.75 parts by weight of malonic acid were mixed. A solvent of PGMEA/EL=6/4 was added so as to adjust polymer solid content concentration of the siloxane polymer A and the siloxane polymer B in total to 2.5 mass %.

Si concentration of the solid content in the composition of the present example for forming the resist underlayer film was 31 mass % (calculated from the mixing ratio). This value can be assumed as equivalent to the Si concentration of the resist underlayer film to be formed. A resist underlayer film formed by using the composition for forming the resist underlayer film had a refractive index (n value) of 1.52, and an attenuation coefficient (k value) of 0.15 for light of 193 nm wavelength. A resist underlayer film formed by using the composition for forming the resist underlayer film had the refractive index (n value) of 1.65, and the attenuation coefficient (k value) of 0.01 for light of 248 nm wavelength. The refractive index and the attenuation coefficient were measured by using “Wvase32” manufactured by J. A. Woollam Co., Inc.

### Example 2

Fifty parts by weight of the siloxane polymer A2, fifty parts by weight of the siloxane polymer B, 0.3 parts by weight of hexadecyltrimethylammoniumacetate, and 0.75 parts by weight of malonic acid were mixed. A solvent of PGMEA/EL=6/4 was added so as to adjust polymer solid content concentration of the siloxane polymer A and the siloxane polymer B in total to 2.5 mass %.

Si concentration of the solid content in the composition of the present example for forming the resist underlayer film was 33 mass % (calculated from the mixing ratio). This value can be assumed as equivalent to the Si concentration in the resist underlayer film to be formed. A resist underlayer film formed by using the composition for forming the resist underlayer film had a refractive index (n value) of 1.68, and an attenuation coefficient (k value) of 0.14 for light of 193 nm wavelength. A resist underlayer film formed by using the composition for forming the resist underlayer film had the refractive index (n value) of 1.58, and the attenuation coefficient (k value) of 0.00 for light of 248 nm wavelength.

### Comparative Example 1

Fifty parts by weight of the siloxane polymer A3, fifty parts by weight of the siloxane polymer B, 0.3 parts by weight of hexadecyltrimethylammoniumacetate, and 0.75 parts by weight of malonic acid were mixed. A solvent of PGMEA and EL of PGMEA/EL=6/4 was added so as to adjust polymer solid content concentration of the siloxane polymer A and the siloxane polymer B in total to 2.5 mass %.

Si concentration of the solid content in the composition of the present example for forming the resist underlayer film was 30 mass % (calculated from the mixing ratio). This value can be assumed as equivalent to the Si concentration in the resist underlayer film to be formed. A resist underlayer film formed by using the composition for forming the resist underlayer film had a refractive index (n value) of 1.50, and an attenuation coefficient (k value) of 0.15 for light of 193 nm wavelength. A resist underlayer film formed by using the composition for forming the resist underlayer film had the refractive index (n value) of 1.67, and the attenuation coefficient (k value) of 0.02 for light of 248 nm wavelength.

[Preparation of Composition for Forming Organic Bottom Layer]

The following were mixed: 100 parts by weight of a copolymer as shown in the following Formula where (α): (β)=75:25 (molar ratio), 20 parts by weight of a glycoluril crosslinking agent (product name: NIKALAC MX 270, manufactured by SANWA Chemical Co., Ltd), 1 part by weight of an additive (product name: Catalyst 602, manufactured by Nihon Cytec Industries Inc.), and 0.05 parts by weight of a fluorosurfactant (product name: XR-104, manufactured by DIC Corporation). A solvent of ethyl lactate and propyleneglycol monomethyl ether acetate of ethyl lactate/propyleneglycol monomethyl ether acetate=2/3 (weight ratio) is added so as to adjust solid content concentration to 12 mass %. Thus, the composition for forming the organic bottom layer is prepared.

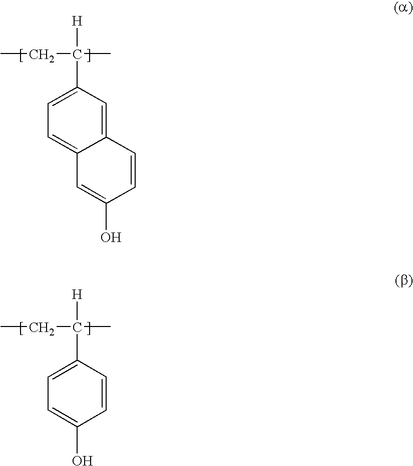

[Pattern Forming]

The organic composition for forming the bottom layer was applied on a silicon wafer by using a common resist coater, and was processed by heat at a temperature of 250° C. for 90 seconds. This formed the organic bottom layer of a thickness of 300 nm. Next, the composition for forming the resist underlayer film of Example 1 or 2 is applied on the organic bottom layer, and was processed by heat at a temperature of 250° C. for 90 seconds. This formed the resist underlayer film of a thickness of 50 nm. Thereafter, a resist film was formed by applying a resist composition on the resist underlayer film. Then, pattern forming was performed as follows the resist film was exposed and developed by the ArF excimer laser, thereafter etched.

As for the resist composition, each of the following components, i.e. a resin, an acid generator, an acid quencher, and additives were combined together in a solvent of PCMEA and EL of PGMEA/EL=60/40 (weight ratio) with solid content concentration adjusted to 6.3 mass %. More specifically, a resist composition which contains the following components was used: Resin: 100 parts by weight of resin which includes a unit (C1:C2:C3=30:50:20 (molar ratio), molecular amount of 10,000) as represented by Formula (16) as follows:

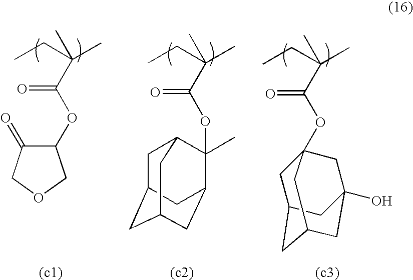

Acid generator: 13 parts by weight of a compound as represented by Formula (17) as follows:

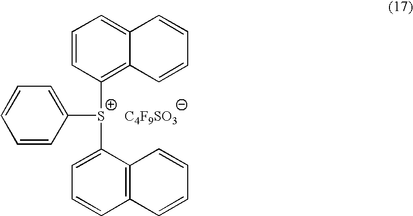

Acid quencher: 0.54 parts by weight of tri-n-pentylamine; and Additives: 10 parts by weight of y-butyrolactone, 1.32 parts by weight of salicylic acid, and 0.10 parts by weight of a surfactant (product name: XR-104, manufactured by DIC Corporation).

[Pattern Evaluation]

Each of the patterns formed in Examples and Comparative Example was evaluated. The patterns were evaluated by observing the state of the patterns in an enlarged state by using an SEM (scanning electron microscope). The evaluation resulted that, although Comparative Example had a resist footing, the resist patterns of each of the Examples had a rectangular pattern with high perpendicularity to the surface of the resist underlayer film. No sign of resist footing or undercut were seen in the resist patterns of the Examples. As such, the present Examples confirmed that a good matching property was obtained between the resist underlayer film and the resist film, regardless of the resist composition.

The present invention is not limited to the description of the embodiments above, but may be altered by a skilled person within the scope of the claims. An embodiment based on a proper combination of technical means disclosed in different embodiments is encompassed in the technical scope of the present invention.

According to the present invention, by thus having, in a siloxane polymer component, a repeating unit which contains a monovalent organic group containing a sulfur atom, it is possible to provide a composition for forming a resist underlayer film capable of forming a resist underlayer film having an improved matching property with the resist, and a resist underlayer film formed with the composition for forming the resist underlayer film.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

Particularly, the present invention provides a composition for forming a resist underlayer film which is suitably used in formation of microscopic patterns in semiconductor processing.

What is claimed is:

1. A composition for forming a resist underlayer film therefrom, the composition comprising a siloxane polymer component which has a repeating unit as represented by General Formula (1) as follows: 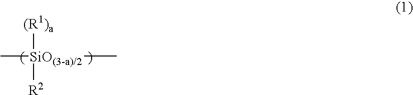
where R¹ is a hydrogen atom or a monovalent organic group, R² is a monovalent organic group containing a sulfur atom, each repeating unit may have different R¹ and/or R² from each other, and a is 0 or 1.

2. The composition as set forth in claim 1, wherein a proportion of the sulfur atom with respect to a silicon atom in the siloxane polymer component is in a range of 5 to 50 mol %.

3. The composition as set forth in claim 1, wherein R² is one of an aliphatic group containing a sulfur atom, and a heterocyclic group containing a sulfur atom.

4. The composition as set forth in claim 1, wherein R² is an organic group containing a mercapto group.

5. The composition as set forth in claim 1, wherein the siloxane polymer component further has a repeating unit as represented by General Formula (2) as follows: 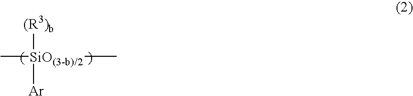
where R³ is a hydrogen atom or a monovalent organic group, Ar is a phenyl group, a naphthyl group, an anthracene group or a phenanthrene group, each repeating unit may have different R³ and/or Ar from each other, and b is 0 or 1.

6. The composition as set forth in claim 1, wherein the siloxane polymer component further has a repeating unit as represented by Genera Formula (3) as follows: 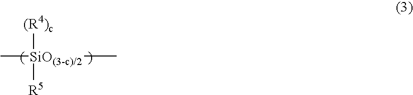
where R⁴ is a hydrogen atom, an alkyl group, a hydroxyl group, a cross-linkable monovalent organic group, or a monovalent organic group which contains at least one functional group selected from the group consisting of a hydroxyl group, a polyether group, a carbonyl group, an ester group, a lactone group, an amide group, an ether group, and a nitrile group, R⁵ is a hydrogen atom or a C1 to C3 alkyl group, each repeating unit may have different R⁴ and/or R⁵ from each other, and c is 0 or 1.

7. The composition of a resist underlayer film as set forth in claim 1, wherein the siloxane polymer component comprises a siloxane polymer having at least two types of the repeating units as represented by General Formula (1), General Formula (2), and General Formula (3),
General Formula (2) being as follows: 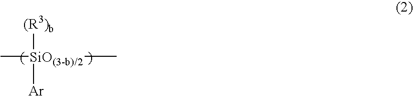
where R³ is a hydrogen atom or a monovalent organic group, Ar is a phenyl group, a naphthyl group, an anthracene group or a phenanthrene group, each repeating unit may have different R³ and/or Ar from each other, and b is 0 or 1, and
General Formula (3) being as follows: 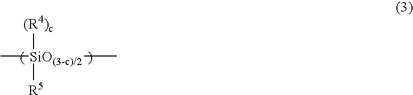
where R⁴ is a hydrogen atom, an alkyl group, a hydroxyl group, a cross-linkable monovalent organic group, or a monovalent organic group which contains at least one functional group selected from the group consisting of a hydroxyl group, a polyether group, a carbonyl group, an ester group, a lactone group, an amide group, an ether group, and a nitrile group, 15 is a hydrogen atom or a C1 to C3 alkyl group, each repeating unit may have different R⁴ and/or R⁵ from each other, and c is 0 or 1.

8. A resist underlayer film prepared by:
performing application of a composition as set forth in claim 1; and
heating the applied composition.
